(19) United States
(12) Patent Application Publication
(10) Pub. No.: US 2026/0255535 A1
(43) Pub. Date: Aug. 27, 2026

(54) INFORMATION HANDLING SYSTEM HAVING LIQUID CONNECTOR COVER WITH LEAKAGE ABSORPTION AND DETECTION CAPABILITIES

(71) Applicant: DELL PRODUCTS L.P., Round Rock, TX (US)

(72) Inventors: Chao-Hung Li, New Taipei City (TW); Wen-Hung Lu, Taipei (TW); Yu-Hung Wang, Tainan City (TW)

(21) Appl. No.: 19/064,900

(22) Filed: Feb. 27, 2025

(51) Int. Cl. H05K 7/20; G01M 3/16; G01N 27/04

(52) U.S. Cl. CPC H05K 7/20272; G01M 3/16; H05K 7/20254; G01N 27/048

(57) ABSTRACT

A system is disclosed and includes a cooling distribution unit and a cold plate in fluid communication with the cooling distribution unit. The cold plate includes at least one fluid connection and a cover fitted over the at least one fluid connection. The cover includes a humidity sensor within the interior of the cover. The humidity sensor providing an initial humidity value within the cover. The system further includes an information handling system having a memory to communicate with the humidity sensor to store the initial humidity value and a processor adjacent the cold plate to communicate with the memory and the humidity sensor. The processor to determine a current humidity value within the cover and compare the current humidity value to the initial humidity value.

### FIELD OF THE DISCLOSURE

The present disclosure generally relates to information handling systems, and more particularly relates to monitoring liquid coolant in an information handling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A system is disclosed and includes a cooling distribution unit and a cold plate in fluid communication with the cooling distribution unit. The cold plate includes at least one fluid connection and a cover fitted over the at least one fluid connection. The cover includes a humidity sensor within the interior of the cover. The humidity sensor providing an initial humidity value within the cover. The system further includes an information handling system having a memory to communicate with the humidity sensor to store the initial humidity value and a processor adjacent the cold plate to communicate with the memory and the humidity sensor. The processor to determine a current humidity value within the cover and compare the current humidity value to the initial humidity value.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of computing system according to an embodiment of the present disclosure;

FIG. 2 is a perspective view of a cooling plate having a fluid connection cover according to an embodiment of the present disclosure;

FIG. 3 is a cross-section view of the cooling plate of FIG. 2 taken along Line 3 -3 in FIG. 2;

FIG. 4 is a perspective view of a fluid connection cover according to an embodiment of the present disclosure;

FIG. 5 is a flow diagram of a method for monitoring liquid coolant in an information handling system according to an embodiment of the present disclosure; and

FIG. 6 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

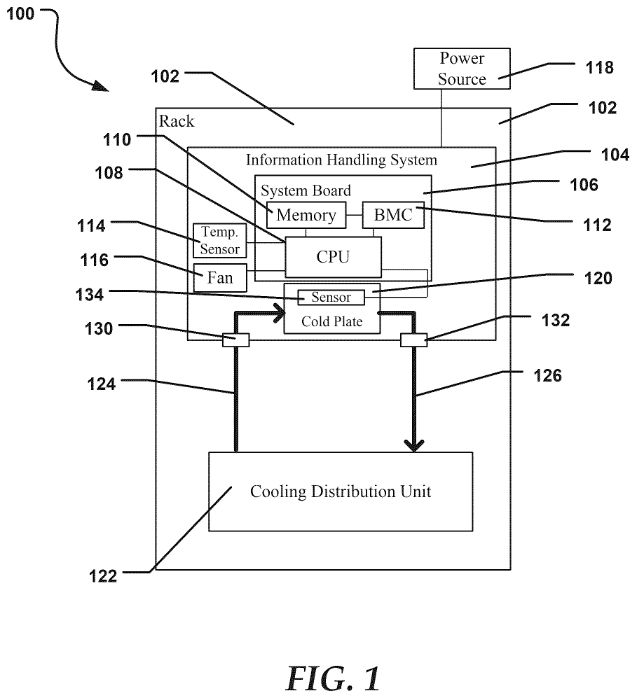

FIG. 1 illustrates a system 100 that may include a rack 102, or cabinet, in which an information handling system 104 is installed, or otherwise disposed. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

As shown, the information handling system 104 may include a system board 106, or motherboard, on which a central processing unit (CPU) 108 is installed, or otherwise disposed. The information handling system 104 may also include a memory 110 coupled to the CPU 108. Moreover, a baseboard management controller 112 may be disposed on the system board 106 and may be coupled to the CPU 108 and the memory 110. Other components necessary to the operation of the information handling system 104, and well known in the art, may be disposed on the system board 106. The information handling system 104 may also include a temperature sensor 114, a fan 116 adjacent the CPU 108, and a leak sensor 118. For example, the leak sensor 118 may be an optical light sensor. Additionally, the information handling system 104 may be coupled to a power source 119. The power source 119 may be an alternating current (AC) power source, a direct current (DC) power source, or a combination thereof. The power source 119 may provide power to all of the components described herein that required power to operate.

FIG. 1 further illustrates a cooling plate 120 adjacent the system board 106. Specifically, the cooling plate 120 is adjacent the CPU 108 which may generate and emit a substantial amount of heat during operation of the information handling system 104. A cooling distribution unit 122 may be connected to the cooling plate 120 via a coolant supply line 124 and a coolant return line 126. A first quick disconnect 130 may be disposed, or otherwise installed, along the supply line 124 upstream from the cooling plate 120, such as at an inlet of the information handling system 104 that leads to the cooling plate 120. Moreover, a second quick disconnect 132 may be disposed, or otherwise installed, along the return line 126 downstream from the cooling plate 120, i.e., at an outlet of the information handling system 104 that leads away from the cooling plate 120. The information handling system 104 may further a fluid sensor 134 (or moisture sensor) on, or adjacent to, the cold plate 120 to detect the presence of unwanted fluid.

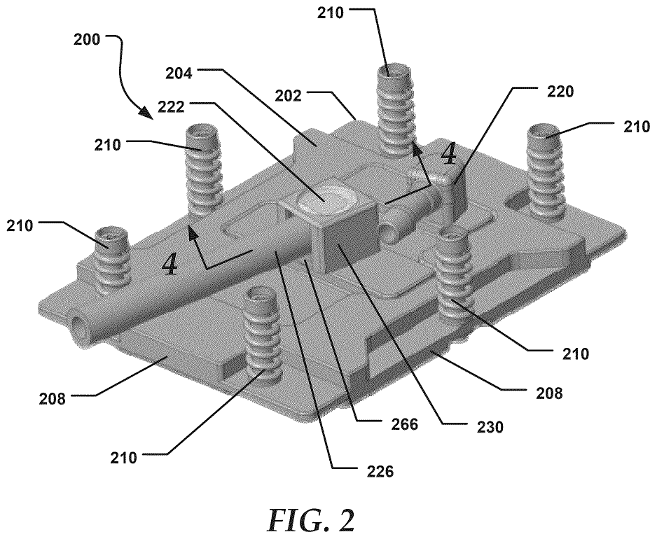

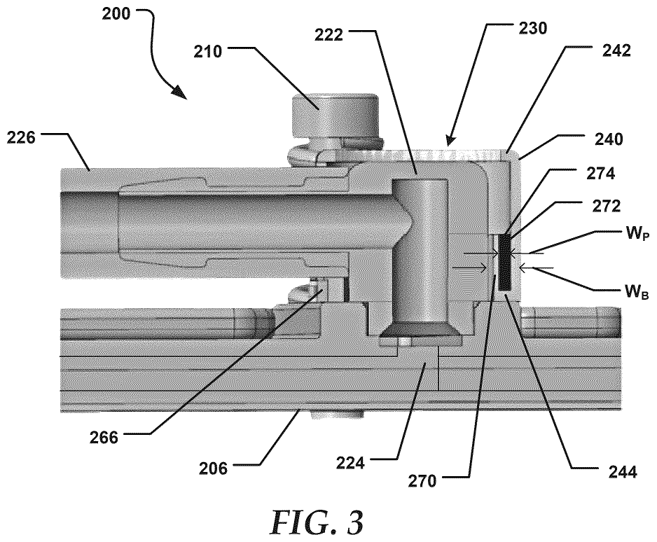

Referring now to FIGS. 2 and 3, a cold plate 200 is illustrated. The cold plate 200 may be the same as the cold plate 120 and may be installed in the information handling system 104 in the same manner as described above. As shown, the cold plate 200 includes a body 202 that includes an upper surface 204, a lower surface 206, and a plurality of sidewalls 208 that extend between the upper surface 204 and lower surface 206. Moreover, a plurality of fasteners 210 may extend through the cold plate 200, i.e., through the upper surface 204 and lower surface 206 of the body 202. The fasteners 210 may be used to mount the cold plate 200 adjacent to, or on, a central processing unit (CPU) or other heat generating component that requires heat dissipation.

The cold plate 200 may include a plurality of fluid connectors. For example, the cold plate 200 includes an inlet barb 220 that extends from the upper surface 204 of the body 202 of the cold plate 200. An outlet barb 222 also extends from the upper surface 204 of the body 202 of the cold plate 200. The cold plate 200 further includes one or more internal channels 224 extending between the inlet barb 220 and the outlet barb 222 within the body 202 of the cold plate 200. FIG. 2 shows a fluid outlet line 226, e.g., a hose, connected to the outlet barb 222. A fluid inlet line may be connected to the inlet barb 220, but is omitted for clarity. Further, as shown, a fluid connector cover 230 may be fitted over the outlet barb 222 and a portion of the fluid outlet line 226 coupled thereto. A similar cover may be fitted over the inlet barb 220 and a fluid inlet line, but is omitted for clarity of discussion.

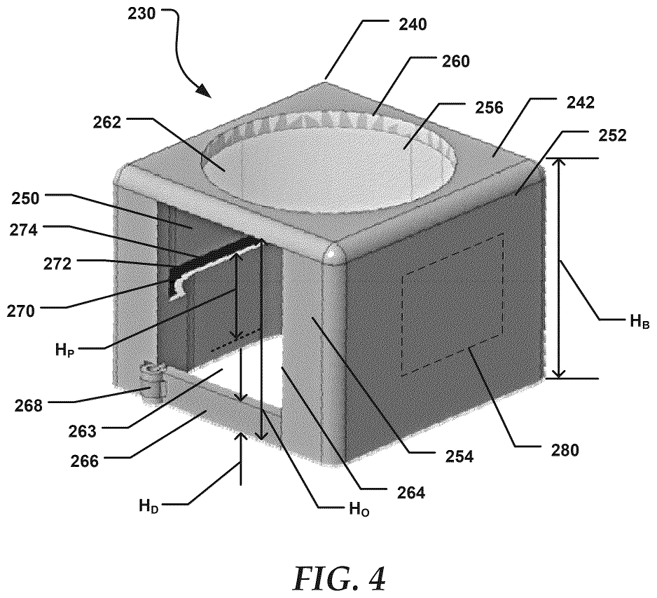

FIGS. 3 and 4 illustrate the details of the fluid connection cover 230. As depicted, the fluid connection cover 230 includes a hollow body 240 that includes an upper surface 242 and a lower surface 244. A left outer wall 250 extends between the upper surface 242 and the lower surface 244 and is substantially perpendicular to the upper surface 242 and the lower surface 244. A right outer wall 252 extends between the upper surface 242 and the lower surface 244 spaced apart from, and opposite to, the left outer wall 250. The right outer wall 252 is substantially parallel to the left outer wall 250. A front outer wall 254 and a rear outer wall 256 extend between the upper surface 242 and the lower surface 244 and between the left outer wall 250 and the right outer wall 252. The front outer wall 254 and rear outer wall 256 are parallel to each other, perpendicular to the upper surface 242 and lower surface 244, and perpendicular to the left outer wall 250 and the right outer wall 252.

As further illustrated, the upper surface 242 of the body 240 of the fluid connection cover 230 is formed with a central bore 260 and a transparent window 262 is glued, press-fit, or otherwise affixed, therein. As such, it is to be understood that the upper surface 242 is fully enclosed. The lower surface 244 is formed with a generally rectilinear first opening 263 that is sized and shaped to allow the fluid connection cover 230 to be fitted over a portion of the outlet barb 222 and a portion of the fluid outlet line 226 as shown. The front outer wall 254 is formed with a generally rectilinear second opening 264 that is sized and shaped to fit around the fluid outlet line 226 and the outlet barb 222 as indicated in FIG. 3. The second opening 264 is substantially perpendicular to the first opening 263. Moreover, the fluid connection cover 230 further includes a door 266 that rotates about a hinge 268 to partially fill the opening 264 in the front outer wall 254. Specifically, as best illustrated in FIGS. 2 and 3, when closed, the door 266 extends beneath the fluid outlet line 226.

In a particular aspect, the opening 264 in the front outer wall 254 has a height, H_{O}, that is measured between the bottom of the opening 264 and the top of the opening 264. Also, the door 266 has a height, H_{D}, that is measured from the bottom of the door 266 to the top of the door 266. In particular, H_{D} is less than H_{O}. For example, H_{D} is less than or equal to 30.0% H_{O}, less than or equal to 27.5% H_{O}, less than or equal to 25.0% H_{O}, less than or equal to 22.5% H_{O}, less than or equal to 20.0% H_{O}, or less than or equal to 17.5% H_{O}. Further, H_{D} is greater than or equal to 5.0% H_{O}, greater than or equal to 7.5% H_{O}, greater than or equal to 10.0% H_{O}, greater than or equal to 12.5% H_{O}, or greater than or equal to 15.0% H_{O}. Moreover, in another aspect, H_{D} is approximately equal to 16.0% H_{O}. It is to be understood that H_{D} may be within a range between, and including, any of the maximum and minimum values of H_{D} described herein.

FIGS. 3 and 4 further show that the body 240 of the fluid connection cover 230 includes an inner wall 270 that extends from the lower surface 244 partially along the lengths of the left outer wall 250, the rear outer wall 256, and the right outer wall 252. The inner wall 270 is spaced apart from the left outer wall 250, the rear outer wall 256, and the right outer wall 252 to form a pocket 272 in which a hydrophilic polymer 274 is disposed. For example, the hydrophilic polymer 274 is a hydrogel with an indicator dye.

In a particular aspect, as shown in FIG. 4, the pocket 272 formed between the inner wall 270 and the outer walls 250, 252, 256 defines a height, H_{P}, that is measured between the bottom of the pocket 272 and the top of the pocket 264. Also, the body 240 of the fluid connection cover 230 includes an overall height, H_{B}, that is measured between the upper surface 242 and the lower surface 244. H_{P} is less than H_{B}. For example, H_{P} is less than or equal to 60.0% H_{B}, less than or equal to 55.0% H_{B}, less than or equal to 50.0% H_{B}, less than or equal to 45.0% H_{B}, or less than or equal to 40.0% H_{B}. Further, H_{P} is greater than or equal to 25.0% H_{B}, greater than or equal to 27.5% H_{B}, greater than or equal to 30.0% H_{B}, greater than or equal to 32.5% H_{B}, greater than or equal to 35.0% H_{B}, or greater than or equal to 37.5% H_{B}. Moreover, in another aspect, H_{P} is approximately equal to 38.0% H_{B}. It is to be understood that H_{P} may be within a range between, and including, any of the maximum and minimum values of H_{P} described herein.

In a particular aspect, as shown in FIG. 4, the pocket 272 defines a width, W_{P}, that is measured between the inner wall 270 and any of the outer walls 250, 252, 254. Also, the body 240 of the fluid connection cover 230 includes an overall width, W_{B}, that is measured between an inner surface of the inner wall 270 and an outer surface of any of the outer walls 250, 252, 254. W_{P} is less than W_{B}. For example, W_{P} is less than or equal to 50.0% W_{B}, less than or equal to 45.0% W_{B}, less than or equal to 40.0% W_{B}, or less than or equal to 35.0% W_{B}. Further, W_{P} is greater than or equal to 10.0% W_{B}, greater than or equal to 15.0% W_{B}, greater than or equal to 20.0% W_{B}, greater than or equal to 25.0% W_{B}, or greater than or equal to 30.0% W_{B}. Moreover, in another aspect, W_{P} is approximately equal to 33.0% W_{B}. It is to be understood that W_{P} may be within a range between, and including, any of the maximum and minimum values of W_{P} described herein.

FIG. 4 shows that the fluid connection cover 230 further includes a leakage sensor 280 that is capable of detecting moisture or fluid leaks, e.g., at the interface of the fluid outlet 226 and the outlet barb 222. For example, the leakage sensor 280 is a resistive humidity sensor, i.e., a hygristor, that is capable of measuring the humidity within the fluid connection cover 230. An initial humidity value within the cover 230 may be determined and then, periodically, current humidity values may be measured and compared to the initial humidity value to determine whether the humidity increases.

Accordingly, in the event of a leak within the fluid connection cover 230, the leakage sensor 280 is configured to detect an increase in humidity within the interior space of the fluid connection cover 230, e.g., as the hydrophilic polymer 274 within the pocket 272 absorbs fluid and expands in the presence of a leak within the fluid connection cover 230. As described in further detail below, the leakage sensor 280 may send an alarm signal to power off the information handling system in which the fluid connection cover 230 is installed to prevent failure and loss of data. Further, in the event of a leak within the fluid connection cover 230, the hydrophilic polymer 274 can absorb fluid and constrain the fluid within the interior of the fluid connection cover 230. Confining fluid to the interior of the fluid connection cover 230 can minimize, or substantially prevent, fluid from exiting the barb cove 230 and potentially causing harm to electrical components outside of the fluid connection cover 230. The indicator dye will allow a user to quickly ascertain the location of any leaks by visually observing the presence of the color of the dye in the transparent window 262 disposed in the upper surface 242 of the body 240 of the fluid connection cover 230.

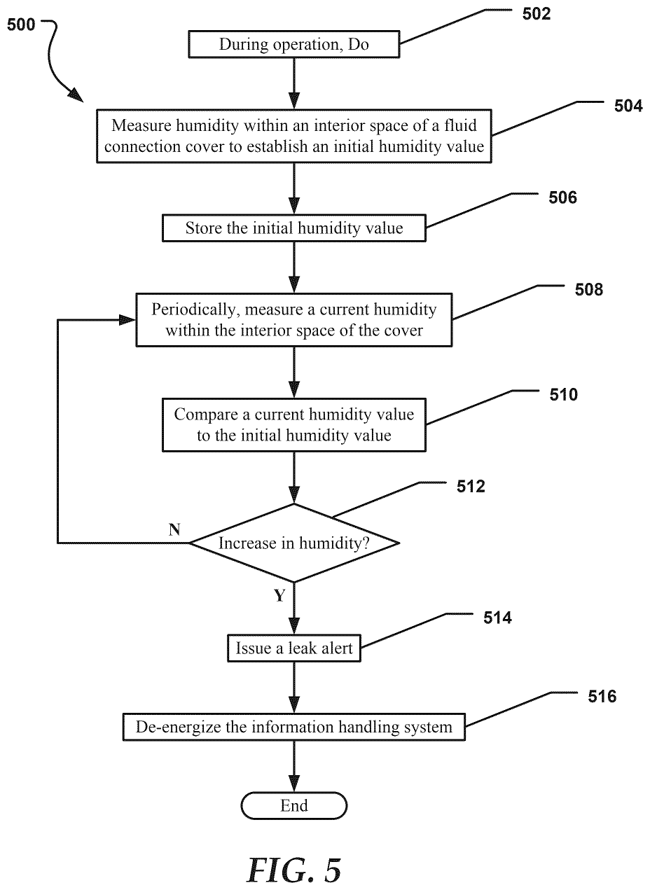

FIG. 5 is a flow diagram of a method 500 for monitoring liquid coolant in an information handling system. Specifically, the method 500 may be used for detecting liquid coolant leaks in an information handling system using the leakage sensor 280 within the fluid connection cover 230 according to at least one embodiment of the present disclosure, starting at block 502. It will be readily appreciated that not every method step set forth in this flow diagram is always necessary, and that certain steps of the methods may be combined, performed simultaneously, in a different order, or perhaps omitted, without varying from the scope of the disclosure. The method steps depicted in FIG. 5 may be executed, or employed in whole, or in part, by the baseboard management controller 112, the CPU 108 of the information handling system 104, a combination thereof, or any other type of controller, device, module, processor, or any combination thereof, operable to employ, or otherwise execute, all, or portions of, the method 500 of FIG. 5.

Beginning at block 502, the method 500 may include entering a do loop in which during operation, the following steps are performed. At block 504, the method may include measuring the humidity within the interior space of a fluid connection cover, e.g., the fluid connection cover 230 disclosed herein. For example, the humidity may be measured using the leakage sensor 280 within the fluid connection cover 230 in order to establish an initial humidity value. At block 506, the method 500 may include storing the initial humidity value, e.g. in a memory such as the memory 110.

Moving to block 508, the method 500 may include periodically measuring a current humidity within the interior space of the fluid connection cover, e.g., using the leakage sensor 280. Then, at block 510, the method 500 may include comparing the current humidity value to the initial humidity value. At decision 512, the method 500 may include determining whether the current humidity value is greater than the initial humidity value and therefore, indicating the likely presence of a fluid leak within the fluid connection cover and the information handling system. If the current humidity value is not greater than the initial humidity value, the method 500 may return to block 508 and the method 500 may continue as described herein.

On the other hand, at decision 512, if the current humidity value is greater than the initial humidity value, the method 500 may continue to block 514 and the method 500 may include issuing a leak alert. Thereafter, at block 516, the method 500 may include de-energizing the information handling system 104 to prevent, or minimize, damage to the internal components of the information handling system 104. The method 500 may then end.

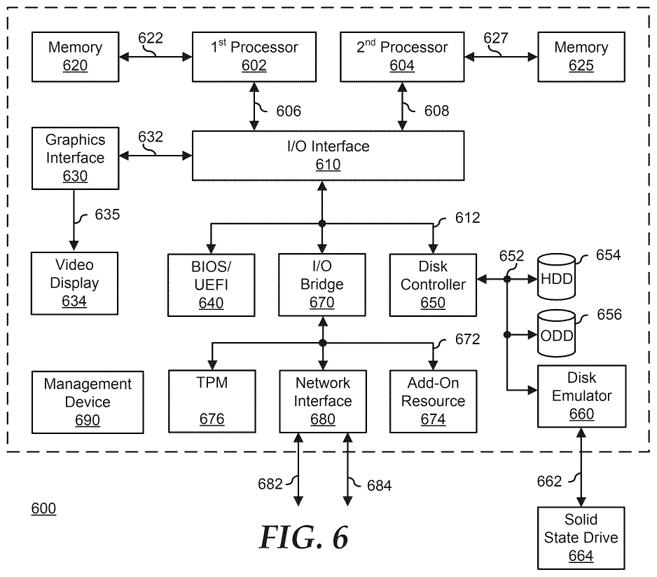

FIG. 6 shows a generalized embodiment of an information handling system 600 according to an embodiment of the present disclosure. Information handling system 600 may be substantially similar to the information handling system 104 of FIG. 1. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 600 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 600 can include processing resources for executing machine-executable code, such as a central processing unit (CPU), a programmable logic array (PLA), an embedded device such as a System-on-a-Chip (SoC), or other control logic hardware. Information handling system 600 can also include one or more computer-readable medium for storing machine-executable code, such as software or data. Additional components of information handling system 600 can include one or more storage devices that can store machine-executable code, one or more communications ports for communicating with external devices, and various input and output (I/O) devices, such as a keyboard, a mouse, and a video display. Information handling system 600 can also include one or more buses operable to transmit information between the various hardware components.

Information handling system 600 can include devices or modules that embody one or more of the devices or modules described below and operates to perform one or more of the methods described herein. Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 664, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 664, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632 and provides a video display output 636 to a video display 634. In a particular embodiment, information handling system 600 includes separate memories that are dedicated to each of processors 602 and 604 via separate memory interfaces. An example of memories 620 and 625 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources. BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 6394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612 or can be a different type of interface. As such, I/O bridge 670 extends the capacity of I/O channel 612 when peripheral interface 672 and the I/O channel are of the same type, and the I/O bridge translates information from a format suitable to the I/O channel to a format suitable to the peripheral channel 672 when they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600.

Management device 690 can operate off of a separate power plane from the components of the host environment so that the management device receives power to manage information handling system 600 when the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A system comprising:
a cooling distribution unit;
a cold plate in fluid communication with the cooling distribution unit, the cold plate including at least one fluid connection;
a cover fitted over the at least one fluid connection, the cover including a humidity sensor within an interior of the cover, the humidity sensor providing an initial humidity value within the cover; and
an information handling system comprising:
a memory to communicate with the humidity sensor to store the initial humidity value; and
a processor adjacent the cold plate to communicate with the memory and the humidity sensor, the processor to:
determine a current humidity value within the cover; and
compare the current humidity value to the initial humidity value.

2. The system of claim 1, wherein the processor further to:
determine whether the current humidity value is greater than the initial humidity value.

3. The system of claim 2, wherein the processor further to:
issue a leak alert when the current humidity value is greater than the initial humidity value.

4. The system of claim 1, wherein the humidity sensor is a resistive humidity sensor.

5. The system of claim 3, wherein the processor further to:
de-energize the information handling system.

6. The system of claim 1, wherein the cover comprises:
an outer wall;
an inner wall; and
a pocket between the outer wall and the inner wall.

7. The system of claim 6, further comprising:
a hydrophilic polymer disposed within the pocket.

8. The system of claim 7, wherein the hydrophilic polymer includes hydrogel and dye.

9. A cover for a fluid connection, the cover comprising:
a body having:
an upper surface;
a lower surface;
at least one outer wall extending between the upper surface and the lower surface;
an inner wall extending from the lower surface and spaced apart from the at least one outer wall to form a pocket between the inner wall and the outer wall; and
a hydrophilic polymer disposed within the pocket.

10. The cover of claim 9, wherein the at least one outer wall includes:
a left outer wall extending between the upper surface and the lower surface;
a right outer wall extending between the upper surface and the lower surface spaced apart from and opposite the left outer wall;
a rear outer wall extending between the upper surface and the lower surface; and
a front outer wall extending between the upper surface and the lower surface spaced apart from and opposite the left outer wall.

1. The cover of claim 10, wherein the upper surface is formed with a bore therethrough and a cap further comprises a transparent window disposed in the bore.

12. The cover of claim 10, wherein the lower surface is formed with a first opening that is sized and shaped to allow the cover to be fitted over a portion of the fluid connection.

13. The cover of claim 12, wherein the front outer wall includes a second opening perpendicular to the first opening.

14. The cover of claim 13, wherein the cover further includes a door rotatably disposed on a hinge to partially fill the second opening.

2. The cover of claim 9, further comprising:
a leakage sensor disposed within the body.

3. The cover of claim 15, wherein the leakage sensor is a humidity sensor.

4. A method of determining fluid leaks within an information handling system, the method comprising:
measuring an initial humidity value within an interior space of a fluid connection cover;
storing the initial humidity value; and
periodically, measuring a current humidity value within the fluid connection cover.

18. The method of claim 17, further comprising:
comparing the current humidity value to the initial humidity value.

19. The method of claim 17, further comprising:
determining whether the current humidity value is greater than the initial humidity value.

20. The method of claim 17, further comprising:
issuing a leak alert when the current humidity value is greater than the initial humidity value.
